(19) United States
(12) Patent Application Publication
(10) Pub. No.: US 2007/0119570 A1
(43) Pub. Date: May 31, 2007

(54) WATER-COOLING HEAT DISSIPATION SYSTEM

(76) Inventors: Ming-Chien Kuo, Taipei County (TW); Tsung-Cheng Huang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/307,392

(22) Filed: Feb. 6, 2006

(30) Foreign Application Priority Data
Nov. 29, 2005 (TW) 94220689

(51) Int. Cl. H05K 7/20

(52) U.S. Cl. 165/80.4; 361/699; 257/714

(57) ABSTRACT

A heat dissipation system including at least a water block, a pump, a water cooler and a plurality of hard tubes is provided. The water block is used to contact a heat source, and the pump is used to circulate the liquid coolant to remove heat generated by the heat source. In addition, the water cooler is used to cool the liquid coolant passing through the water block, and the hard tubes are connected to the water block, the pump, and the water cooler to form a circulation tube. At least a buffer material is set in the hard tubes for regulating the pressure within the circulation tube.

### CROSS-REFERENCE TO RELATED APPLICATION

This application claims the priority benefit of Taiwan application serial no. 94220689, filed on Nov. 29, 2005. All disclosure of the Taiwan application is incorporated herein by reference.

### BACKGROUND OF THE INVENTION

1. Field of the Invention

The present invention relates to a water-cooling heat dissipation system, and more particularly to a water-cooling heat dissipation system in which a pressure within a tube is regulated.

2. Description of Related Art

In a computer system, the CPU, the north bridge chip, the south bridge chip, and the graphic chip, etc., on a motherboard are integrated circuit (IC) chips, and the IC chip generates heat during operation. In order to rapidly remove the heat generated by the IC chips from the motherboard, a water-cooling heat dissipation system is utilized, wherein a water block is used to directly contact the back of the IC chip, and the heat is transferred to a cooler by coolant circulating through the water block. Generally, the water cooler is equipped outside the housing of a computer, and comprises an inlet port, and an outlet port connected to a water tank, and a fan for cooling the circulating coolant within the water cooler. Additionally, the water tank may be equipped with a pump for circulating the coolant such that the coolant flows towards the water block and then back to the tank. Thus, the heat generated by the operation of the ICs may be transferred by the circulating coolant and removed.

However, hoses are required for connecting the water block, the tank and the pump of the water-cooling heat dissipation system, and while the differential circulating pressures within the hose may easily cause leakage at connecters and joints of the hoses. Some proposed using metallic tubes instead of hoses in order to overcome the aforementioned leakage problem; however, since the temperature of the liquid coolant rises during the operation of the system, resulting in a change of the fluid volume, the pressure in the metallic tube is accordingly increased, and when pressure exceeds a pressure limit of the system, there will be risks of explosion.

### SUMMARY OF THE INVENTION

An object of the present invention is to provide a water-cooling heat dissipation system, wherein the pressure in the circulation tube is regulated by a pressure buffer mechanism.

The water-cooling heat dissipation system includes a water block, a pump, a water cooler and a plurality of hard tubes. The water block is used to contact a heat source, and the pump is used to transfer the liquid coolant to the water block and to transfer heat generated by the heat source. In addition, the water cooler is used to cool the liquid coolant passing through the water block, and the hard tubes are connected to the water block, the pump and the water cooler respectively to form a circulation tube; wherein, at least a buffer material is set within the hard tubes for regulating the pressure in the circulating system.

A water-cooling heat dissipation system according to another embodiment of the present invention is provided. The water-cooling heat dissipation system includes a liquid-heat dissipation mechanism, a water cooler and a plurality of hard tubes. The liquid-heat dissipation mechanism includes a housing, a cooling plate module and a driving device. The cooling plate module is disposed on the bottom edge of the housing to contact a heat source, while the driving device is disposed within the housing and connected to the cool plate module. The driving device is adopted for circulating a liquid coolant passing through the cooling plate module to dissipate the heat generated by the heat source. Furthermore, the water cooler is used to cool the liquid coolant passing through the cooling plate module, and the hard tubes are connected to the liquid-heat dissipation mechanism and the water cooler to form a circulation tube; wherein at least a buffer element is set in the hard tubes for regulating the pressure in the circulation tube.

According to one embodiment of the present invention, the above-mentioned hard tubes are provided with a protruding portion with a larger diameter respectively, and the buffer material is positioned surrounding the inner wall of the protruding portion.

According to one embodiment of the present invention, the above-mentioned hard tubes are provided with a protruding portion with a larger diameter respectively, and the buffer material is positioned within the protruding portion.

According to one embodiment of the present invention, the above-described protruding portion is formed by a jointing tube with a larger diameter.

According to one embodiment of the present invention, the volume of the above-described buffer material can be changed as the pressure within the tube changes.

Since a pressure buffer structure is employed in the present invention, the volume can be changed as the pressure within the tube changes; thereby the pressure within the circulation tube can be regulated. Therefore, heat generated due to high speed operations of components, such as the CPU, chipsets, and graphic chips in a computer system can be quickly removed through the heat dissipation system of the present invention. Thus, not only the problem of hose leakage can be resolved, but also for the pressure within the circulation tube can be regulated. Thus, the reliability of the product can be effectively promoted.

In order to make the aforementioned and other objects, features, and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a water-cooling heat dissipation system according to one embodiment of the present invention.

FIGS. 2-4 depict schematic cross-sectional views of a pressure buffer mechanism respectively according to specific embodiments of the present invention.

FIG. 5 is a schematic view of a water-cooling heat dissipation system according to another embodiment of the present invention.

### DESCRIPTION OF EMBODIMENTS

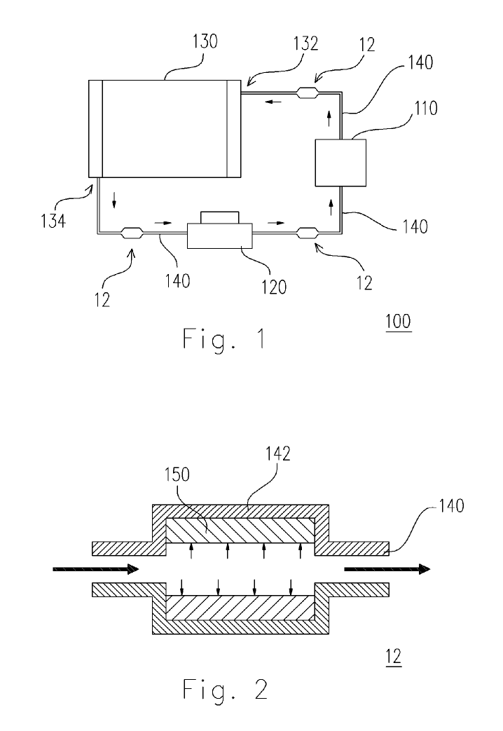

FIG. 1 is a schematic view of a water-cooling heat dissipation system according to one embodiment of the present invention. Referring to FIG. 1, a water-cooling heat dissipation system 100 includes a water block 110, a pump 120, a water cooler 130 and a plurality of hard tubes 140. The water block 110 is used to contact a heat source (not shown), wherein the hard tubes are comprised of, e.g., metals with a high thermal conductivity, such as copper and aluminum. The pump 120 is used to press the liquid coolant (indicated by the arrow) to the water block 110 to remove the heat generated by the heat source. In addition, the water cooler 130 has an inlet port 132 and an outlet port 134. The liquid coolant absorbs the waste heat from the heat source and flows into the water cooler 130 through the inlet port 132 where the liquid coolant can be cooled down through an internal heat exchange, and finally flows out through the outlet port 134. Thereafter the cooled liquid coolant is returned to the water block 110 by the pump 120. Thus, the liquid coolant passes through the circulation tube described above. It should be noted that hard tubes 140 are employed in the present invention for connecting the water block 110, the pump 120 and the water cooler 130, and the like so as to avoid a problem of leakage at connections and joints of the hard tubes forming the circulation tube. However, in order to avoid excessive high pressure within the hard tubes 140, a pressure buffer mechanism 12 is set in the circulation tube or the systematic element to regulate the change of volume or pressure of the liquid coolant within the circulation tube, such that the volume can be changed through compression and deformation when the pressure within the tube increases. Three types of pressure buffer mechanism 12 in the specific embodiments of the present invention will be illustrated in detail below:

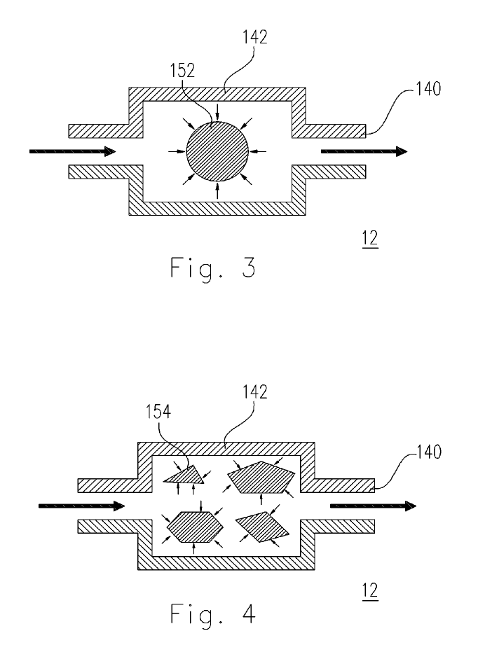

FIGS. 2-4 depict schematic cross-sectional views of a pressure buffer mechanism respectively according to specific embodiments of the present invention. First, referring to FIG. 2, the hard tubes 140 are made of metallic tubes, with a buffer material 150 set on the inner wall to regulate the pressure within the tube. The buffer material 150 can be disposed within a protruding portion 142 with a larger diameter of the hard tube 140, or one jointing tube with a larger diameter can be sleeved to the hard tube 140. When the liquid coolant passes through the space surrounded by the buffer material 150, the water pressure exerts a pressure to force the buffer material 150 outwards, such that its volume shrinks, so as to prevent excessive high pressure within the hard tube. Next, referring to FIGS. 3 and 4, different amounts of buffer materials with different shapes, e.g., a single spherical buffer material 152 of FIG. 3, or multiple irregular buffer materials 154 of FIG. 4, also can be placed within the hard tube 140 to regulate the pressure within the tube. The buffer materials 152, 154 can be disposed in a protruding portion 142 with a larger diameter of the hard tube 140, or one jointing tube with a larger diameter is sleeved to the hard tube 140. When the liquid coolant 20 passes through a space around the buffer material 152, 154, the pressure is exerted and forces the buffer material 152, 154 inwards, such that its volume shrinks so as to prevent excessive high pressure within the hard tube.

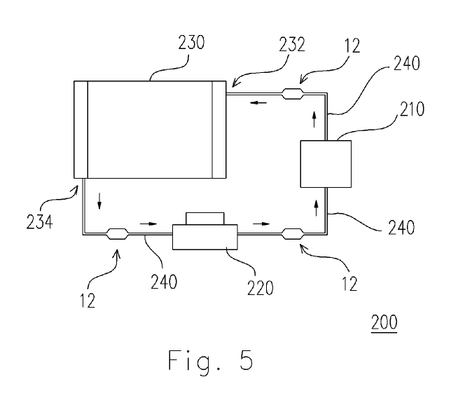

FIG. 5 depicts a schematic view of a water-cooling heat dissipation system according to another embodiment of the present invention. Referring to FIG. 5, the water-cooling heat dissipation system 200 includes a water block 210, a liquid-heat dissipation mechanism 220, a water cooler 230 and a plurality of hard tubes 240 with a pressure buffer structure 12 used to avoid the excessively high pressure within the tube. The water block 210 can be disposed on a heat source (not shown), and the liquid-heat dissipation mechanism 220 can be disposed on another heat source (not shown); and the water block 210, the liquid-heat dissipation mechanism 220 and the water cooler 230 are connected with each other by hard tubes 240 to form a circulation tube to circulate the liquid coolant, such that the liquid coolant takes away the waste heat from the heat source and is cooled down on the way of flowing from the water inlet port 232 to the water outlet port 234. The liquid-heat dissipation mechanism 220 further includes a housing, a cooling plate module disposed on the bottom edge of the housing, and a driving device disposed within the housing, which is only schematically showed in the figure. The cooling plate module is used to contact the heat source, and the driving device is connected to the cool plate module to circulate the liquid coolant through the cool plate module to remove the heat generated by the heat source. It should be noted that, the liquid-heat dissipation mechanism 220 has a combined structure of the driving device and the cooling plate module with the functions of both circulating the liquid coolant and absorbing the heat. The details can be obtained with reference to the specification of Taiwan Patent No. M273031 liquid-heat dissipation mechanism, which will not be described any more herein in detail.

As described in the above-mentioned embodiments, when the buffer element is compressed under pressure, its volume is shrunk so that the space created can be used as a buffer space compensate the increased volume caused by the fluid expansion, such that the pressure within the tube will not rise significantly, thus preventing excessive high pressure within the hard tube to avoid bursting or explosion.

Above all, a buffer material is set in the hard tube employed in a water-cooling heat dissipation system of the present invention, wherein the volume of the buffer material can be changed as the pressure within the tube changes, thereby regulating the pressure within the tube. Thus, heat generated due to operations of the components, such as, the CPU, chipsets, and graphic chips in a computer system can be removed quickly through a water-cooling heat dissipation system of the present invention. The water-cooling heat dissipation system not only prevents the problem of leakage but also regulates the pressure within the tube. Thus, the reliability of the product can be effectively promoted.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A water-cooling heat dissipation system, comprising:
at least one water block, suitable for contacting at least one heat source;
a pump, for transferring a liquid coolant to the water block to dissipate heat generated by the heat source;
a water cooler, for cooling the liquid coolant passing through the water block; and
a plurality of hard tubes, connected to at least one water block, the pump, and the water cooler respectively to form a circulation tube, wherein at least one buffer element is set in the hard tubes for regulating a pressure of the liquid coolant within the hard tubes.

2. The water-cooling heat dissipation system as claimed in claim 1, wherein the hard tubes are provided with at least one protruding portion with a larger diameter respectively, and a buffer material is disposed surrounding an inner wall of the protruding portion.

3. The water-cooling heat dissipation system as claimed in claim 2, wherein the protruding portion is formed by a jointing tube with a larger diameter.

4. The water-cooling heat dissipation system as claimed in claim 1, wherein the hard tubes are provided with at least one protruding portion with a larger diameter respectively, and a buffer material is disposed within the protruding portion.

5. The water-cooling heat dissipation system as claimed in claim 4, wherein the protruding portion is formed by a jointing tube with a larger diameter.

6. A water-cooling heat dissipation system, comprising:
a liquid-heat dissipation mechanism, including a housing, a cooling plate module disposed on a bottom edge of the housing for contacting a heat source, and a driving device disposed in the housing and connected with the cooling plate module; wherein the driving device transfers a liquid coolant passing through the cooling plate module to remove heat generated by the heat source;
a water cooler, for cooling the liquid coolant passing through the cooling plate module; and
a plurality of hard tubes, connected to the liquid-heat dissipation mechanism and the water cooler respectively to form a circulation tube, wherein at least one buffer element is set in the hard tubes for regulating a pressure of the liquid coolant within the hard tubes.

7. The water-cooling heat dissipation system as claimed in claim 6, further comprising at least one water block connected to the circulation tube, wherein the liquid coolant flowing into at least one water block via the hard tubes is adopted to remove heat generated by at least another heat source.

8. The water-cooling heat dissipation system as claimed in claim 6, wherein the hard tubes are provided with at least one protruding portion with a larger diameter respectively, and the buffer material is disposed surrounding an inner wall of the protruding portion.

9. The water-cooling heat dissipation system as claimed in claim 8, wherein the protruding portion is formed by a jointing tube with a larger diameter.

10. The water-cooling heat dissipation system as claimed in claim 6, wherein the hard tubes are provided with at least one protruding portion with a larger diameter respectively, and the buffer material is disposed within the protruding portion.

11. The water-cooling heat dissipation system as claimed in claim 10, wherein the protruding portion is formed by a jointing tube with a larger diameter.
